(19) United States
(12) Patent Application Publication
(10) Pub. No.: US 2026/0047121 A1
(43) Pub. Date: Feb. 12, 2026

(54) TRANSISTOR DIRECT BACKSIDE CONTACT WITH ETCH STOP LAYER

(71) Applicant: Applied Materials, Inc., Santa Clara, CA (US)

(72) Inventors: Sai Hooi Yeong, Cupertino, CA (US); Benjamin Colombeau, San Jose, CA (US); Veeraraghavan S. Basker, Fremont, CA (US); Balasubramanian Pranatharthiharan, San Jose, CA (US)

(73) Assignee: Applied Materials, Inc., Santa Clara, CA (US)

(21) Appl. No.: 18/799,152

(22) Filed: Aug. 9, 2024

(51) Int. Cl. H01L 29/66; H01L 21/033; H01L 21/283; H01L 21/308; H01L 29/06; H01L 29/417; H01L 29/423; H01L 29/775; H01L 29/786

(52) U.S. Cl. CPC H10D 30/014; H01L 21/0332; H01L 21/283; H01L 21/3081; H10D 62/021; H10D 64/015; H10D 64/258; H10D 30/43; H10D 30/6735; H10D 30/6757; H10D 62/121

(57) ABSTRACT

Semiconductor devices and methods of manufacturing the same are described. A silicon wafer is provided and an etch stop bilayer is formed on the silicon wafer. The insertion of an etch stop bilayer in the starting wafer will serve as an etch stop for deep trench formation on the wafer frontside and for wafer backside planarization. With this approach variations in the sacrificial material depth in a GAA device and substrate thickness may offer benefits in lithography overlay control.

### TECHNICAL FIELD

Embodiments of the disclosure generally relate to semiconductor devices. More particularly, embodiments of the disclosure are directed to logic devices in general, particularly focusing on gate-all-around (GAA) devices having etch stop layers in the starting superlattice structure, and methods of manufacturing gate-all-around (GAA) devices and other transistor devices.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Semiconductor devices are typically fabricated by sequentially depositing insulating or dielectric layers, conductive layers, and semiconductor layers of material over a semiconductor substrate, and patterning the various material layers using lithography to form circuit components and elements thereon. The conductive layers facilitate electrical wiring to various electrical components including transistors, amplifiers, inverters, control logic, memory, power management circuits, buffers, filters, resonators, capacitors, inductors, resistors, and the like.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, FinFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a gate all around (GAA) structure. The GAA device structure includes several lattice matched channels suspended in a stacked configuration and connected by source/drain regions. The GAA structure provides good electrostatic control and can find broad adoption in complementary metal oxide semiconductor (CMOS) wafer manufacturing.

Current methods of manufacture for gate-all-around (GAA) devices rely upon direct backside contact (DBC) process flows having large source drains deep recess etch and chemical mechanical planarization (CMP) variations. Accordingly, there is a need for gate-all-around (GAA) devices and methods of manufactures which the reduce the etch and CMP process variations.

### SUMMARY

One or more embodiments of the disclosure are directed to methods of forming a semiconductor device. In one or more embodiments, a method of forming a semiconductor device comprises: forming an etch stop bilayer on a top surface of a substrate, the substrate having a frontside and a backside, and the etch stop bilayer comprising a first etch stop layer and a second etch stop layer; from the frontside, etching a deep contact trench to the first etch stop layer and depositing a sacrificial material into the deep contact trench; from the backside: removing a first portion of the substrate until the second etch stop layer is reached; removing a second portion of the substrate until the first etch stop layer is reached; and removing the first etch stop layer to expose the sacrificial material.

Additional embodiments of the disclosure are directed to methods of forming a semiconductor device. In one or more embodiments, a method of forming a semiconductor device comprises: forming an etch stop bilayer on a top surface of a substrate, the etch stop bilayer comprising a first etch stop layer and a second etch stop layer; forming a superlattice structure on a top surface of etch stop bilayer, the superlattice structure comprising a plurality of horizontal channel layers and a corresponding plurality of semiconductor material layers alternatingly arranged in a plurality of stacked pairs; forming a gate structure on a top surface of the superlattice structure; forming a plurality of source trenches and a plurality of drain trenches adjacent to the superlattice structure on the substrate; expanding at least one of the plurality of source trenches and at least one of the plurality of drain trenches to form a source cavity and a drain cavity, stopping at the first etch stop layer; from the backside, selectively removing selectively removing a first portion of the substrate by one or more of grinding, chemical mechanical planarization (CMP), and reactive ion etching, stopping at the second etch stop layer; from the backside, selectively removing a second portion of the substrate by one or more of grinding, chemical mechanical planarization (CMP), and reactive ion etching, stopping at the first etch stop layer; and removing the first etch stop layer to expose a contact region on the backside.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a process flow diagram of a method according to one or more embodiments;

FIG. 1B is a continuation of the process flow diagram of FIG. 1A depicting a method according to one or more embodiments;

FIG. 2 illustrates a cross-section view of a device according to one or more embodiments;

FIG. 3A illustrates a cross-section view of a device according to one or more embodiments;

FIG. 3B illustrates a cross-section view of a device according to one or more embodiments;

FIG. 4A illustrates a cross-section view of a device according to one or more embodiments;

FIG. 4B illustrates a cross-section view of a device according to one or more embodiments;

FIG. 4C illustrates a cross-section view of a device according to one or more embodiments;

FIG. 4D illustrates a cross-section view of a device according to one or more embodiments;

FIG. 4E illustrates a cross-section view of a device according to one or more embodiments;

FIG. 4F illustrates a cross-section view of a device according to one or more embodiments; and

FIG. 5 illustrates a cluster tool according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor,” “reactant”, “reactive gas” and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated I_{S} and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double-or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In the method of one or more embodiments, transistors, e.g., gate all-around transistors, are fabricated using a standard process flow. In some embodiments, a silicon wafer is provided and an etch stop bilayer is formed on the silicon wafer. The etch stop bilayer may include a first etch stop layer and a second etch stop layer. In one or more embodiments, the first etch stop layer serves as an etch stop layer when etching the deep contact trench from the frontside of the wafer. The etching of the deep contact trench stop substantially on the first etch stop layer. The first etch stop layer also serves as a CMP stop layer when etching from the backside of the wafer. In one or more embodiments, the second etch stop layer serves as a CMP stop layer from the backside.

In one or more embodiments, when the etch stop bilayer is used during GAA processing, after formation of the etch stop bilayer, an epitaxial layer, e.g., epitaxial silicon, is deposited. The wafer is then subjected to device and front-end processing. After the source/drain cavity is recessed, the dimension of the source/drain cavity is expanded, and a sacrificial fill material is deposited. Fabrication proceeds with formation of the inner spacer, source/drain epitaxy, replacement metal gate formation, and silicide and contact formation. The substrate is then flipped and planarized, stopping on the first SiGe layer of the etch stop bilayer. In one or more embodiments, this may help to essentially attain uniform thickness of the remaining layers with negligible variation. In one or more embodiments, the silicon layer within each etch stop bilayer is then removed, stopping on the second SiGe layer of the etch stop bilayer. Backside isolation then proceeds. In one or more embodiments, the sacrificial fill material is advantageously selective so that, upon etching, self-aligned trenches and/or vias are formed, thus avoiding misalignment. In other embodiments, when the etch stop bilayer is used for 4F2 DRAM cell and capacitor, the etch stop bilayer could be used as an etch stop from the frontside for a DRAW word line contact.

In one or more embodiments, a silicon wafer is provided and an etch stop bilayer is advantageously formed on the silicon wafer. In one or more embodiments, the etch stop bilayer is for transistor silicon layer thinning processes, e.g., 4F2 DRAM cell and capacitor, or direct backside contact formation for gate-all-around (GAA) devices. The insertion of an etch stop bilayer in the starting GAA superlattice substrate advantageously serves as an etch stop for deep source/drain recess for sacrificial material deposition and the wafer backside planarization. With this approach variations in the sacrificial material depth and substrate thickness may offer benefits in lithography overlay control.

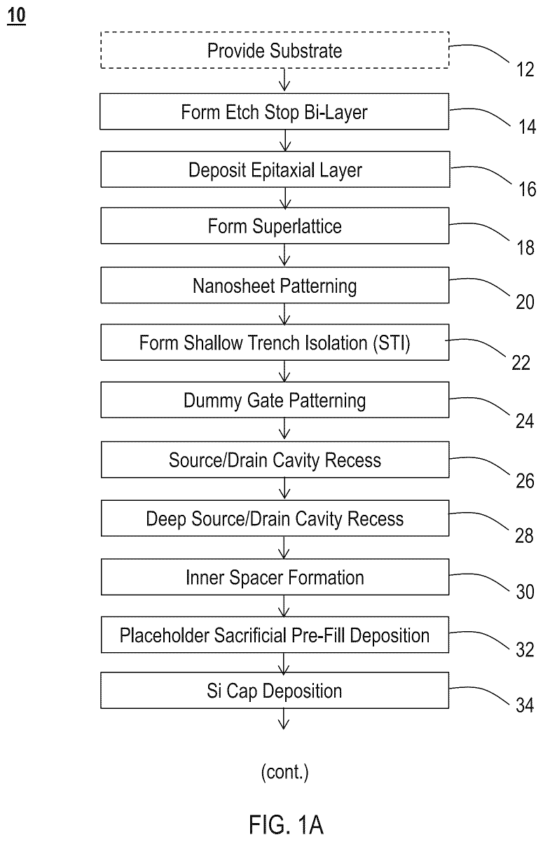

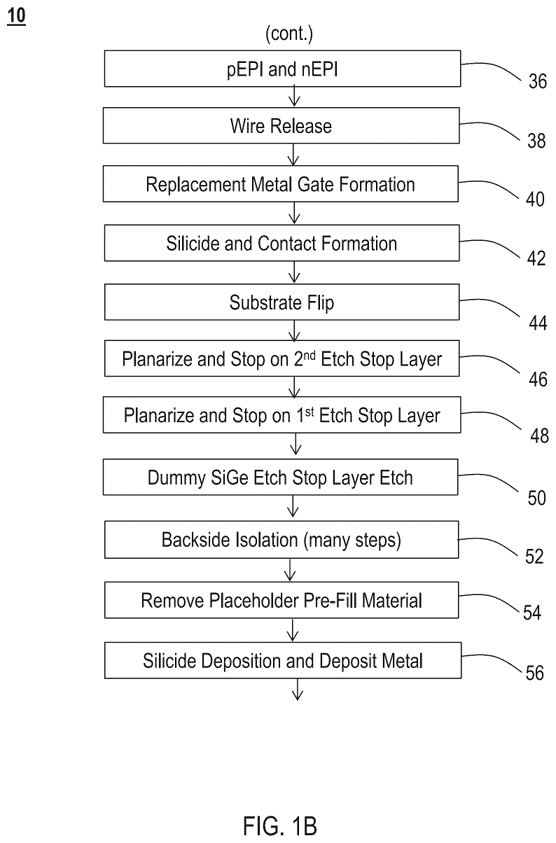

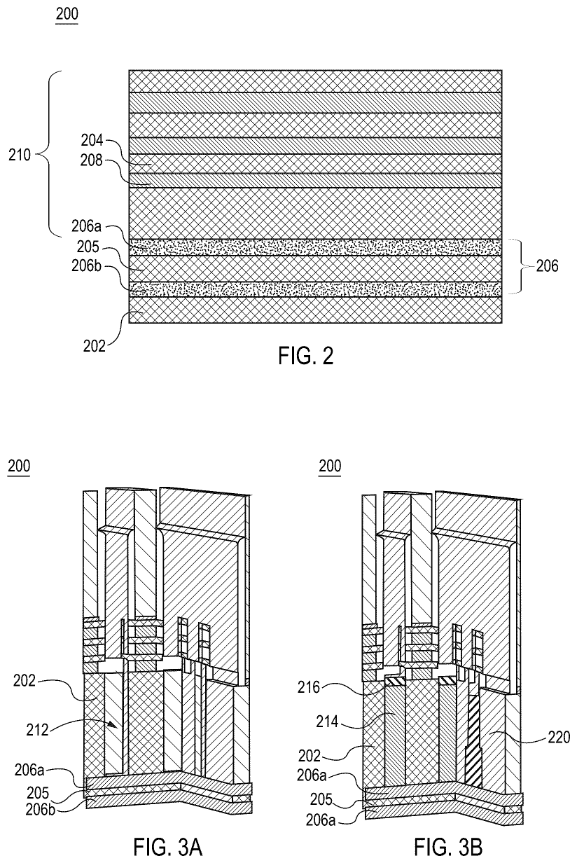

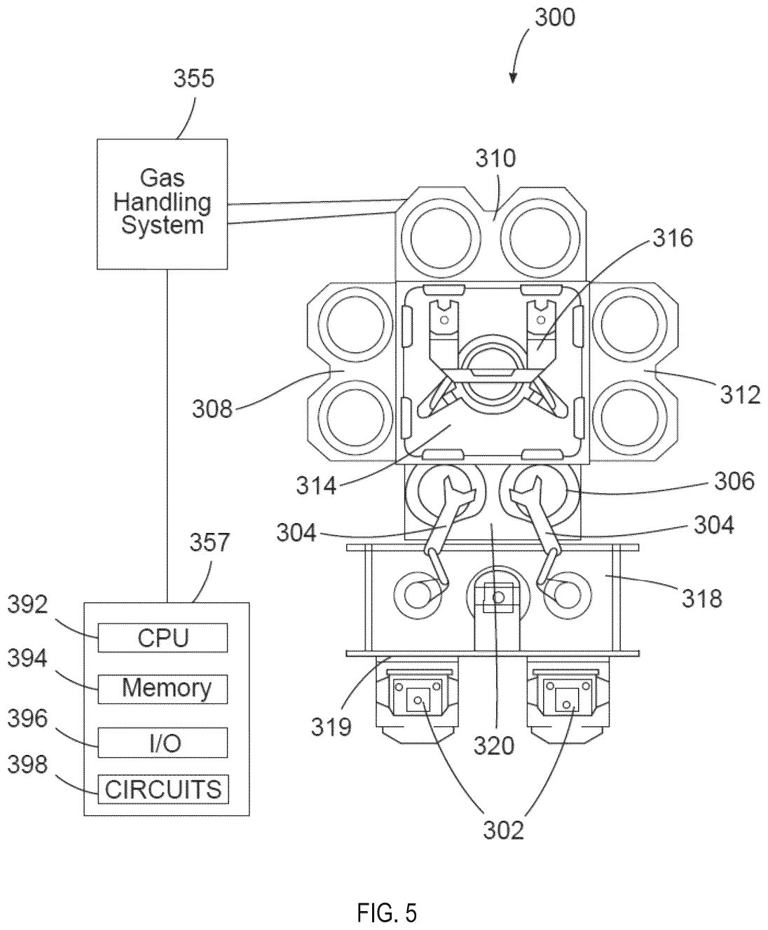

FIG. 1A illustrates a process flow diagram for a method 10 for forming a semiconductor device in accordance with some embodiments of the present disclosure. FIG. 1B is a continuation of the process flow diagram of FIG. 1A depicting the method 10 according to one or more embodiments. FIGS. 2, 3A-3B, and 4A-4F depict the stages of fabrication of semiconductor structures in accordance with some embodiments of the present disclosure. The method 10 is described below with respect to FIGS. 2, 3A-3B, and 4A-4F. FIGS. 2, 3A-3B, and 4A-4F are cross-sectional views of an electronic device (e.g., a GAA) according to one or more embodiments. The method 10 may be part of a multi-step fabrication process of a semiconductor device. Accordingly, the method 10 may be performed in any suitable process chamber coupled to a cluster tool. The cluster tool, such as that illustrated in FIG. 5, may include process chambers for fabricating a semiconductor device, such as chambers configured for etching, deposition, physical vapor deposition (PVD), chemical vapor deposition (CVD), oxidation, or any other suitable chamber used for the fabrication of a semiconductor device.

FIGS. 2, 3A-3B, and 4A-4F are the fabrication steps of operations 12 thru 60 in FIGS. 1A-1B. Referring to FIG. 1A, the method 10 of forming the device 200 begins at operation 12, by providing a substrate 202. In some embodiments, the substrate 202 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 202 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 102 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

With reference to FIG. 1A, in some unillustrated embodiments, at operation 14, an etch stop bilayer 206 may be formed on a top surface of the substrate 202. The etch stop bilayer 206 may comprise any suitable material known to the skilled artisan. In one or more unillustrated embodiments, referring to FIG. 1A and FIG. 2, at operation 16, an epitaxial layer 205, e.g., epitaxial silicon, may be deposited on the etch stop bilayer 206. The epitaxial layer 205 may have a thickness is a range of from 20 nm to 100 nm.

Accordingly, in one or more embodiments, as illustrated in FIG. 2, the etch stop bilayer 206 includes a first etch stop layer 206a and a second etch stop layer 206b separated by the epitaxial silicon layer 205.

In one or more embodiments, the etch stop bilayer 206 comprises two layers of silicon germanium (SiGe) 206a and 206b and a silicon layer 205 in between them. In one or more embodiments, the first etch stop layer 206a and the second etch stop layer 206b independently have a germanium (Ge) content in a range of from 5 atomic % to 50 atomic %. In one or more embodiments, the first etch stop layer 206a and the second etch stop layer 206b have different amounts of germanium (Ge) content in order to have different etch selectivity.

Without intending to be bound by theory, it is thought that the germanium content being in a range of from 5 atomic % to 50 atomic % leads to increased selectivity of the etch stop layer and minimizes stress defects. In one or more embodiments, the SiGe layers 206a and 206b independently have a thickness in a range of from 10 nm to 50 nm. In one or more embodiments, the etch stop bilayer 206, particularly the second etch stop layer 206b, may advantageously serve as an etch stop for planarization (e.g., CMP), dry or wet etch during backside processing.

Referring to FIG. 1A and FIG. 2, in one or more embodiments, at operation 18, at least one superlattice structure 210 is formed atop the top surface of the substrate 202 or on a top surface of the etch stop bilayer 206 (e.g., the first etch stop layer 206a, the epitaxial layer 205, and the second etch stop layer 206b). The superlattice structure 210 comprises a plurality of semiconductor material layers 208 and a corresponding plurality of horizontal channel layers 204 alternatingly arranged in a plurality of stacked pairs. In some embodiments the plurality of stacked groups of layers comprises a silicon (Si) and silicon germanium (SiGe) group. In some embodiments, the plurality of semiconductor material layers 208 comprise silicon germanium (SiGe), and the plurality of horizontal channel layers 204 comprise silicon (Si). In other embodiments, the plurality of horizontal channel layers 204 comprise silicon germanium (SiGe), and the plurality of semiconductor materials layers 106 comprise silicon (Si).

In some embodiments, the plurality of semiconductor material layers 208 and corresponding plurality of horizontal channel layers 204 can comprise any number of lattice matched material pairs suitable for forming a superlattice structure 204. In some embodiments, the plurality of semiconductor material layers 208 and corresponding plurality of horizontal channel layers 204 comprise from about 2 to about 50 pairs of lattice matched materials.

In one or more embodiments, the thickness of the plurality of semiconductor material layers 208 and the plurality of horizontal channel layers 204 are in the range of from about 2 nm to about 50 nm, in the range of from about 3 nm to about 20 nm, or in a range of from about 2 nm to about 15 nm.

With reference to FIG. 1A, in one or more embodiments, at operation 20, the superlattice structure 210 is patterned to form an opening between adjacent stacks. The patterning may be done by any suitable means known to the skilled artisan. As used in this regard, the term “opening” means any intentional surface irregularity. Suitable examples of openings include, but are not limited to, trenches which have a top, two sidewalls and a bottom. Openings can have any suitable aspect ratio (ratio of the depth of the feature to the width of the feature). In some embodiments, the aspect ratio is greater than or equal to about 5:1, about 10:1, about 15:1, about 20:1, about 25:1, about 30:1, about 35:1 or about 40:1.

Referring to FIG. 1A, at operation 22, a shallow trench isolation (STI) is formed. As used herein, the term “shallow trench isolation (STI)” refers to an integrated circuit feature which prevents current leakage. In one or more embodiments, STI is created by depositing one or more dielectric materials (such as silicon dioxide) to fill the trench or opening and removing the excess dielectric using a technique such as chemical-mechanical planarization.

Referring to FIG. 1A and FIG. 3A, at operations 26 and 28, in one or more embodiments, source/drain trenches are formed adjacent (i.e., on either side) the superlattice structure 210. In one or more embodiments, the source/drain trenches are deepened and expanded to form cavities 212. The cavities 212 may have any suitable depth and width. In some embodiments, the source/drain trenches are deepened and expanded to form cavities 212 that stop on the first etch stop layer 206a. Thus, in one or more embodiments, the cavity 212 etch and dummy fill extend below the shallow trench isolation and maximally up to the etch stop bilayer 206, thus enabling self-aligned contacts without touching the device.

The cavity 212 may be formed by any suitable means known to the skilled artisan. In one or more embodiments, a hard mask is deposited to block the source/drain. In one or more embodiments, the hard mask may comprise any suitable material known to the skill artisan. In some embodiments, the hard mask is a resist. Once the hard mask is formed, the cavity 21 is formed by etching.

The etch process of operations 26 and 28 may include any suitable etch process that is selective to the source/drain trenches. In some embodiments the etch process of operations 26 and 28 comprises one or more of a wet etch process or a dry etch process. The etch process may be a directional etch.

In some embodiments, the dry etch process may include a conventional plasma etch, or a remote plasma-assisted dry etch process. In a remote plasma-assisted dry etch process, the device is exposed to H₂, NF₃, and/or NH₃ plasma species, e.g., plasma-excited hydrogen and fluorine species. For example, in some embodiments, the device may undergo simultaneous exposure to H₂, NF₃, and NH₃ plasma. The remote plasma-assisted dry etch process may be performed in a preclean chamber, which may be integrated into one of a variety of multi-processing platforms known to the skilled artisan. The wet etch process may include a hydrofluoric (HF) acid last process, i.e., the so-called “HF last” process, in which HF etching of surface is performed that leaves surface hydrogen-terminated. Alternatively, any other liquid-based pre-epitaxial pre-clean process may be employed. In some embodiments, the process comprises a sublimation etch for native oxide removal. The etch process can be plasma or thermally based. The plasma processes can be any suitable plasma (e.g., conductively coupled plasma, inductively coupled plasma, microwave plasma).

Referring to FIG. 1A, at operation 30, an inner spacer layer is formed on each of the horizontal channel layers 204. The inner spacer layer may comprise any suitable material known to the skilled artisan. In one or more embodiments, the inner spacer layer comprises a nitride material. In specific embodiments, the inner spacer layer comprises silicon nitride.

Referring to FIG. 1A and FIG. 3B, at operation 32, a sacrificial material 214 is deposited in the cavity 212. The sacrificial material 214 may comprise any suitable material known to the skilled artisan. In some embodiments, the sacrificial material 214 comprises silicon germanium (SiGe). In one or more embodiments, the sacrificial material 214 has a high germanium (Ge) content. In one or more embodiments, the amount of germanium is in a range of from 10% to 50%, including a range of from 25% to 45%. Without intending to be bound by theory, it is thought that the germanium content being in a range of from 10% to 50% leads to increased selectivity of the sacrificial material and minimizes stress defects.

In one or more embodiments, the sacrificial material 214 is doped with a dopant for lower contact resistance. In some embodiments, the dopant is selected from one or more of carbon (C), boron (B), gallium (Ga), phosphorus (P), arsenic (As), other semiconductor dopants, or combinations thereof. In specific embodiments, the sacrificial material 214 is silicon germanium having a germanium content in a range of from 10% to 50% and doped with a dopant selected from one or more of carbon (C), boron (B), gallium (Ga), phosphorus (P), and arsenic (As).

Referring to FIG. 1A and FIG. 3B, at operation 24 a cap layer 216 is formed on a top surface of the sacrificial material 214. The cap layer 216 may comprise any suitable material known to the skilled artisan. In one or more embodiments, the cap layer comprises silicon (Si). In one or more embodiments, the cap layer 216 may serve to aid in the selective removal of the sacrificial material 214 without adversely impacting the source/drain epitaxial films.

With reference to FIG. 1B, at operations 36, 38, 40, and 42, respectively, the formation of the semiconductor device, e.g., GAA, continues according to traditional procedures with pEPI and nEPI, nanosheet wire release, replacement metal gate formation, and silicide and contact formation. Specifically, in one or more unillustrated embodiments, the plurality of semiconductor material layers 208 are selectively etched between the plurality of horizontal channel layers 204 in the superlattice structure 210. For example, where the superlattice structure 210 is composed of silicon (Si) layers and silicon germanium (SiGe) layers, the silicon germanium (SiGe) is selectively etched to form channel nanowires. The plurality of semiconductor material layers 208, for example silicon germanium (SiGe), may be removed using any well-known etchant that is selective to the plurality of horizontal channel layers 204 where the etchant etches the plurality of semiconductor material layers 208 at a significantly higher rate than the plurality of horizontal channel layers 204. In some embodiments, a selective dry etch or wet etch process may be used. In some embodiments, where the plurality of horizontal channel layers 204 are silicon (Si) and the plurality of semiconductor material layers 208 are silicon germanium (SiGe), the layers of silicon germanium may be selectively removed using a wet etchant such as, but not limited to aqueous carboxylic acid/nitric acid/HF solution and aqueous citric acid/nitric acid/HF solution. The removal of the plurality of semiconductor material layers 208 leaves voids between the plurality of horizontal channel layers 204. The voids between the plurality of horizontal channel layers 204 have a thickness of about 3 nm to about 20 nm. The remaining horizontal channel layers 204 form a vertical array of channel nanowires that are coupled to the source/drain regions. The channel nanowires run parallel to the top surface of the substrate 202 and are aligned with each other to form a single column of channel nanowires.

In one or more embodiments, a high-k dielectric is formed. The high-k dielectric can be any suitable high-k dielectric material deposited by any suitable deposition technique known to the skilled artisan. The high-k dielectric of some embodiments comprises hafnium oxide. In some embodiments, a conductive material such as titanium nitride (TiN), tungsten (W), cobalt (Co), aluminum (Al), or the like is deposited on the high-k dielectric to form the replacement metal gate 224. The conductive material may be formed using any suitable deposition process such as, but not limited to, atomic layer deposition (ALD) in order to ensure the formation of a layer having a uniform thickness around each of the plurality of channel layers.

Referring to FIG. 1B, at operation 42, the contact to transistor (CT) and contact to gate (CG) are formed. In one or more embodiments, at least one contact in electrical contact with the source region and the drain region is formed.

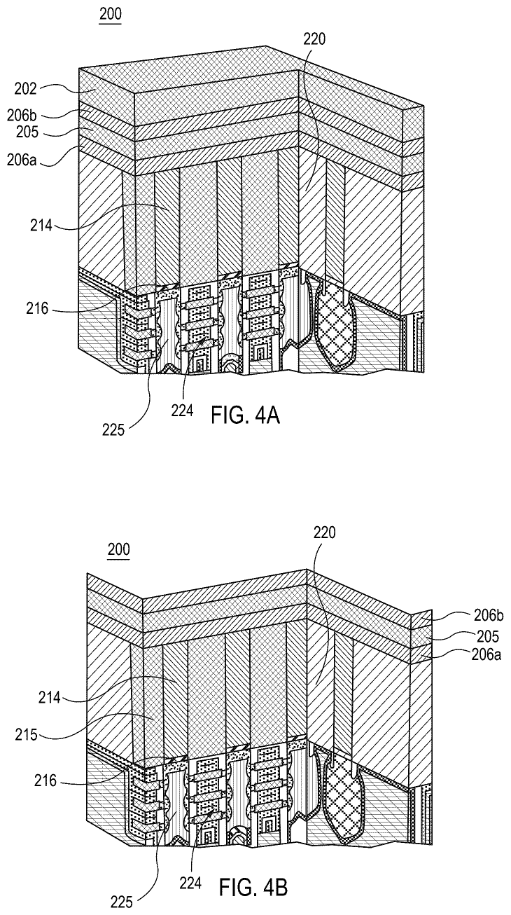

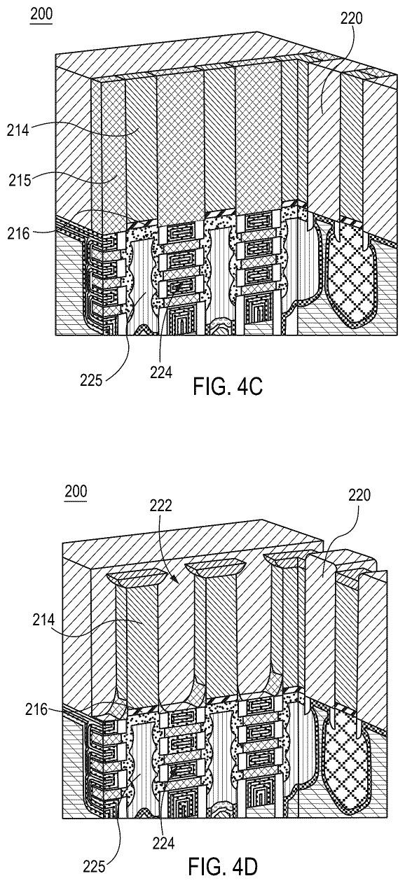

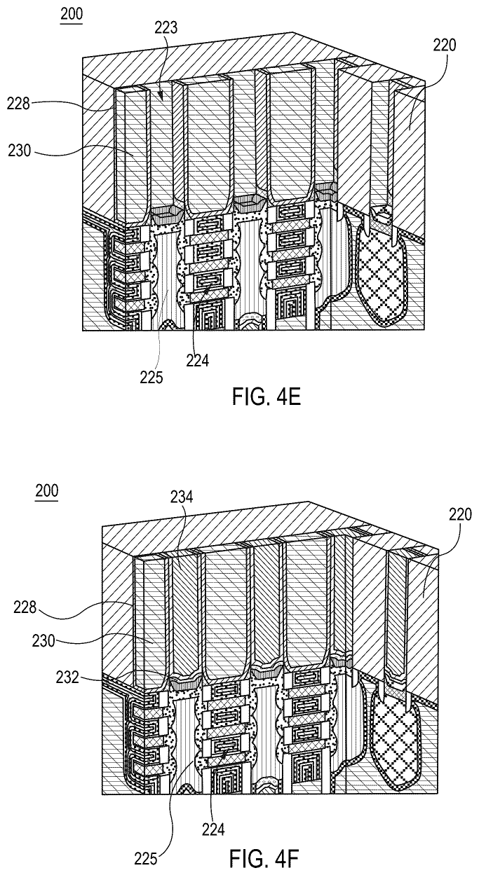

With reference to FIG. 1B and FIG. 4A, at operation 44, the device 200 is rotated or flipped 180 degrees, such that the substrate 202 is now at the top of the illustration. Additionally, referring to FIG. 1B and FIG. 4B, in one or more embodiments, the substrate 202 is planarized at operation 46. The planarization may be any suitable planarization process known to the skill artisan including, but not limited to, wet etching, dry etching, grinding, and chemical mechanical planarization (CMP). In one or more embodiments, the planarization of operation 46 is grinding and removes the substrate 202 and stops at the etch stop bilayer 206. In one or more embodiments, the planarization stops on the second etch stop layer 206b, leaving the first etch stop layer 206a, the epitaxial layer 205, and the second etch stop layer 206b.

Referring to FIG. 1B and FIG. 4C, at operation 48, in one or more embodiments, the device 200 is planarized a second time. The planarization may be any suitable planarization process known to the skill artisan including, but not limited to, wet etching, dry etching, grinding, and chemical mechanical planarization (CMP). In one or more embodiments, the planarization of operation 48 is chemical mechanical planarization and removes the etch stop bilayer 206 and the epitaxial layer 205. In other embodiments, the planarization of operation 48 is chemical mechanical planarization and removes the second etch stop layer 206b and the epitaxial layer 205 but leaves the first etch stop layer 206a. The first etch stop layer 206a may then be removed by reactive ion etching. As illustrated in FIG. 4C, removal of the etch stop bilayer 206, e.g., the first etch stop layer 206a and the second etch stop layer 206b, exposes a top surface of the sacrificial material 214 and a stop surface of the adjacent silicon layer 215. In one or more embodiments, removal of the first etch stop layer 206a allows for subsequent formation of the backside contact.

With reference to FIG. 1B, the processing of the device 200 proceeds according to standard processing at operation 52 for backside isolation. Referring to FIG. 4D, the silicon layer 215 is selectively removed to form an opening 222 adjacent to the sacrificial layer 214. The silicon layer 215 may be selectively removed by any suitable process known to the skilled artisan including any of the etch processes described herein.

Referring to FIG. 1A and FIG. 4E, at operation 54, a nitride liner 228 is formed in the opening 222, followed by formation of an interlayer dielectric (ILD) 230 on the nitride liner 228. In one or more embodiments, the sacrificial layer 214 is selectively removed to form an opening 223 over the source/drain 225. The sacrificial layer 214 may be selectively removed by any suitable process known to the skilled artisan including any of the etch processes described herein.

In one or more embodiments, if the sacrificial layer 214 is doped with one or more of Ga, C, B, P, it may be removed partially leaving some of the sacrificial layer 214 remaining. Partial removal of the sacrificial layer 214 may allow the formation of a low resistivity contact to the remaining sacrificial layer 214 (e.g., SiGe).

At operation 56, as illustrated in FIG. 4F, a silicide layer 232 and a metal fill 234 are deposited in the opening 213 formed by removal of the sacrificial layer 214. The metal fill 234 may comprise any suitable material known to the skilled artisan. In one or more embodiments, the metal fill 234 is selected from one or more of titanium (Ti), titanium nitride (TiN), tantalum (Ta), tantalum nitride (TaN), tungsten (W), molybdenum (Mo), cobalt (Co), copper (Cu), ruthenium (Ru), and the like. In one or more embodiments, the metal fill 234 may be electrically coupled to the source/drain 225 of the transistor device and may be used to provide power to the transistor device.

Processing of the device then proceeds according to standard means.

Additional embodiments of the disclosure are directed to processing tools 300 for the formation of the GAA devices and methods described, as shown in FIG. 5. A variety of multi-processing platforms may be utilized. The cluster tool 300 includes at least one central transfer station 314 with a plurality of sides. A robot 316 is positioned within the central transfer station 314 and is configured to move a robot blade and a wafer to each of the plurality of sides.

The cluster tool 300 comprises a plurality of processing chambers 308, 310, and 312, also referred to as process stations, connected to the central transfer station. The various processing chambers provide separate processing regions isolated from adjacent process stations. The processing chamber can be any suitable chamber including, but not limited to, a pre-clean chamber, a deposition chamber, an annealing chamber, an etching chamber, and the like. The particular arrangement of process chambers and components can be varied depending on the cluster tool and should not be taken as limiting the scope of the disclosure.

In the embodiment shown in FIG. 5, a factory interface 318 is connected to a front of the cluster tool 300. The factory interface 318 includes chambers 302 for loading and unloading on a front 319 of the factory interface 318.

The size and shape of the loading chamber and unloading chamber 302 can vary depending on, for example, the substrates being processed in the cluster tool 300. In the embodiment shown, the loading chamber and unloading chamber 302 are sized to hold a wafer cassette with a plurality of wafers positioned within the cassette.

Robots 304 are within the factory interface 318 and can move between the loading and unloading chambers 302. The robots 304 are capable of transferring a wafer from a cassette in the loading chamber 302 through the factory interface 318 to load lock chamber 320. The robots 304 are also capable of transferring a wafer from the load lock chamber 320 through the factory interface 318 to a cassette in the unloading chamber 302.

The robot 316 of some embodiments is a multi-arm robot capable of independently moving more than one wafer at a time. The robot 316 is configured to move wafers between the chambers around the transfer chamber 314. Individual wafers are carried upon a wafer transport blade that is located at a distal end of the first robotic mechanism.

A system controller 357 is in communication with the robot 316, and a plurality of processing chambers 308, 310 and 312. The system controller 357 can be any suitable component that can control the processing chambers and robots. For example, the system controller 357 can be a computer including a central processing unit (CPU) 392, memory 394, inputs/outputs 396, suitable circuits 398, and storage.

Processes may generally be stored in the memory of the system controller 357 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In some embodiments, the system controller 357 has a configuration to control the rapid thermal processing chamber to crystallize the template material.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a template deposition chamber and a template crystallization chamber; and a controller connected to the central transfer station and the plurality of process stations, the controller configured to activate the robot to move the wafer between process stations, and to control a process occurring in each of the process stations.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
forming an etch stop bilayer on a top surface of a substrate, the substrate having a frontside and a backside, and the etch stop bilayer comprising a first etch stop layer and a second etch stop layer;
from the frontside, etching a deep contact trench to the first etch stop layer and depositing a sacrificial material into the deep contact trench;
from the backside:
removing a first portion of the substrate until the second etch stop layer is reached;
removing a second portion of the substrate until the first etch stop layer is reached; and
removing the first etch stop layer to expose the sacrificial material.

2. The method of claim 1, wherein the first portion of the substrate is removed by grinding, the second portion of the substrate is removed by chemical mechanical planarization (CMP), and the first etch stop layer is removed via etching.

3. The method of claim 1, further comprising removing the sacrificial material to expose a source or drain region.

4. The method of claim 1, wherein the first etch stop layer and the second etch stop layer are separated by an epitaxial layer.

5. The method of claim 4, wherein the epitaxial layer comprises silicon.

6. The method of claim 1, wherein the first etch stop layer and the second etch stop layer independently comprise silicon germanium (SiGe).

7. The method of claim 6, wherein the silicon germanium (SiGe) contains in a range of from 5 atomic % germanium (Ge) to 50 atomic % germanium (Ge).

8. The method of claim 1, wherein the first etch stop layer and the second etch stop layer independently have a thickness in a range of from 100 nm to 50 nm.

9. A method of forming a semiconductor device, the method comprising:
forming an etch stop bilayer on a top surface of a substrate, the etch stop bilayer comprising a first etch stop layer and a second etch stop layer;
forming a superlattice structure on a top surface of etch stop bilayer, the superlattice structure comprising a plurality of horizontal channel layers and a corresponding plurality of semiconductor material layers alternatingly arranged in a plurality of stacked pairs;
forming a gate structure on a top surface of the superlattice structure;
forming a plurality of source trenches and a plurality of drain trenches adjacent to the superlattice structure on the substrate;
expanding at least one of the plurality of source trenches and at least one of the plurality of drain trenches to form a source cavity and a drain cavity, stopping at the first etch stop layer;
from the backside, selectively removing selectively removing a first portion of the substrate by one or more of grinding, chemical mechanical planarization (CMP), and reactive ion etching, stopping at the second etch stop layer;
from the backside, selectively removing a second portion of the substrate by one or more of grinding, chemical mechanical planarization (CMP), and reactive ion etching, stopping at the first etch stop layer; and
removing the first etch stop layer to expose a contact region on the backside.

10. The method of claim 9, further comprising, after forming the source cavity and the drain cavity:
depositing a sacrificial material in the source cavity and in the drain cavity;
depositing a cap layer on a top surface of the sacrificial material;
forming an inner spacer layer on each of the plurality of horizontal channel layers;
forming a source region and a drain region;
forming an interlayer dielectric layer on the substrate;
forming a replacement metal gate;
forming at least one contact in electrical contact with the source region and the drain region; and
rotating the semiconductor device 180 degrees to expose the backside of the substrate.

11. The method of claim 9, wherein expanding at least one of the plurality of source trenches and at least one of the plurality of drain trenches comprises depositing a hard mask on at least one of the plurality of source trenches and on at least one of the plurality of drain trenches and not on at least one of the plurality of source trenches and at least one of the plurality of drain trenches, and etching the unmasked source trench and unmasked drain trench to form the source cavity and the drain cavity.

12. The method of claim 9, wherein the first etch stop layer and the second etch stop layer are separated by an epitaxial layer.

13. The method of claim 9, wherein the first etch stop layer and the second etch stop layer independently comprise silicon germanium (SiGe).

14. The method of claim 13, wherein the silicon germanium (SiGe) contains in a range of from 5 atomic % germanium (Ge) to 50 atomic % germanium (Ge).

15. The method of claim 9, wherein the first etch stop layer and the second etch stop layer independently have a thickness in a range of from 100 nm to 50 nm.

16. The method of claim 9, wherein the sacrificial material is fully removed.

17. The method of claim 9, wherein the sacrificial material comprises silicon germanium (SiGe) having a germanium (Ge) content in a range of from 10% to 50%.

18. The method of claim 17, wherein the silicon germanium (SiGe) is doped with a dopant selected from the group consisting of boron (B), gallium (Ga), phosphorus (P), arsenic (As), and combinations thereof.

19. The method of claim 9, wherein the cap layer comprises silicon.

20. The method of claim 9, wherein the plurality of semiconductor material layers and the plurality of horizontal channel layers independently comprise one or more of silicon germanium (SiGe) and silicon (Si).
